(19) United States
(12) Patent Application Publication
(10) Pub. No.: US 2012/0055701 A1
(43) Pub. Date: Mar. 8, 2012

(54) HIGH PERFORMANCE SURFACE MOUNT ELECTRICAL INTERCONNECT

(75) Inventor: James Rathburn, Mound, MN (US)

(73) Assignee: HSIO TECHNOLOGIES, LLC, Maple Grove, MN (US)

(21) Appl. No.: 13/266,486

(22) PCT Filed: May 25, 2010
(86) PCT No.: PCT/US10/36043

§ 371 Date: Oct. 27, 2011

Related U.S. Application Data
(60) Provisional application No. 61/181,937, filed on May 28, 2009.

(51) Int. Cl. H05K 1/03; B23K 31/02; H05K 1/16; H05K 1/02; H05K 1/09

(52) U.S. Cl. 174/254; 174/255; 174/257; 174/260; 228/165

(57) ABSTRACT

An interconnect assembly including a substrate with a plurality of through holes extending from a first surface to a second surface. A plurality of discrete contact member are located in the plurality of through holes. The contact members include proximal ends that are accessible from the second surface, distal ends extending above the first surface, and intermediate portions engaged with an engagement region of the substrate located between the first surface and the recesses. Retention members are coupled with at least a portion of the proximal ends to retain the contact members in the through holes. The retention members can be made from a variety of materials with different levels of conductivity, ranging from highly conductive to non-conductive.

### TECHNICAL FIELD

The present application relates to a high performance electrical interconnect assembly between an integrated circuit and a printed circuit assembly.

### BACKGROUND OF THE INVENTION

Traditional integrated circuit (IC) sockets are generally constructed of an injection molded plastic insulator housing which has stamped and formed copper alloy contact members stitched or inserted into designated positions within the housing. The designated positions in the insulator housing are typically shaped to accept and retain the contact members. The assembled socket body is then generally processed through a reflow oven which melts and attaches solder balls to the base of the contact member. During final assembly, the socket can be mounted onto a printed circuit assembly. The printed circuit assembly may be a printed circuit board (PCB), the desired interconnect positions on the PCB are printed with solder paste or flux and the socket is placed such that the solder balls on the socket contacts land onto the target pads on the PCB. The assembly is then reheated to reflow the solder balls on the socket assembly. When the solder cools it essentially welds the socket contacts to the PCB, creating the electrical path for signal and power interaction with the system.

During use, the socket receives one or more IC packages and connects each terminal on the IC package to the corresponding terminal on the PCB. The terminals on the IC package are held against the contact members by applying a load to the package, which is expected to maintain intimate contact and reliable circuit connection throughout the life of the system. No permanent connection is required so that the IC package can be removed or replaced without the need for reflowing solder connections.

These types of sockets and interconnects have been produced in high volume for many years. As systems advance to next generation architectures, these traditional devices have reached mechanical and electrical limitations that mandate alternate approaches.

As processors and electrical systems evolve, several factors have impacted the design of traditional sockets. Increased terminal count, reductions in the terminal pitch (i.e., the distance between the contacts), and signal integrity have been main drivers that impact the socket and contact design. As terminal count increases, the IC packages get larger due to the additional space needed for the terminals. As the IC package grows larger the relative flatness of the IC package and corresponding PCB becomes more important. A certain degree of compliance is required between the contacts and the terminal pads to accommodate the topography differences and maintain reliable connections.

IC package manufacturers tend to drive the terminal pitch smaller so they can reduce the size of the IC package and reduce the flatness effects. As the terminal pitch reduces, however, the surface area available to place a contact is also reduced, which limits the space available to locate a spring or a contact member that can deflect without touching a neighbor.

In order to maximize the length of the spring so that it can deflect the proper amount without damage, the thickness of the insulating walls within the plastic housing is reduced. Thinner walls increase the difficulty of molding as well as the latent stress in the molded housing that can cause warping due to heat applied during solder reflow.

For mechanical reasons, longer contact members traditionally have been preferred because they have desirable spring properties. Long contact members, however, tend to reduce the electrical performance of the connection by creating a parasitic effect that impacts the signal as it travels through the contact. Other factors, such as contact resistance, impact self heating as current passes through, for example, power delivery contacts. Also, the small space between contact members can cause distortion as a nearby contact member influences a neighboring contact member, which is known as cross talk.

Traditional sockets and methods of fabricating the same are able to meet the mechanical compliance requirements of today's needs, but they have reached an electrical performance limit. Next generation systems will operate above 5 GHz and beyond and the existing interconnects will not achieve acceptable performance levels without significant revision.

### BRIEF SUMMARY OF THE INVENTION

The present disclosure is directed to electrical interconnects that enable next generation electrical performance. An electrical interconnect assembly according to the present disclosure may include a substrate and a plurality of discrete contact members positioned and secured in a plurality of holes through the substrate. Some of the embodiments can include a high performance interconnect architecture within a socket.

In one embodiment, the contact members can be simple beam structures made of conventional materials, but omit the normal retention features that add parasitic mass and distort or degrade the integrity of the signal as it passes through the contact member. This approach provides a reliable connection to the package terminals and creates a platform to add electrical and mechanical enhancements to the substrate of the socket to address the challenges of next generation interconnect requirements. The lack of contact member retention features greatly reduces the complexity of the contact members and the tooling required to produce them.

The substrate containing the contact members may be inverted to expose the proximal ends of the contact members that will electrically couple with the PCB. This surface of the substrate and the array of exposed proximal ends of the contact members may be processed to achieve contact retention, to add mechanical features to improve the reliability of the solder joint to the PCB, and to provide a platform to add passive and active circuit features to improve electrical performance or internal function and intelligence.

Once the substrate is loaded with contact members, the substrate can be processed as a printed circuit or semiconductor package to add functions and electrical enhancements not found in traditional connectors. In one embodiment, electrical features and devices are printed onto the substrate using, for example, inkjet printing technology, aerosol printing technology, or other printing technology. The ability to enhance the substrate such that it mimics aspects of the IC package and the PCB allows for reductions in complexity for the IC package and the PCB while improving the overall performance of the interconnect assembly.

The printing processes permits the fabrication of functional structures, such as conductive paths and electrical devices, without the use of masks or resists. Features down to about 10 microns can be directly written in a wide variety of functional inks, including metals, ceramics, polymers and adhesives, on virtually any substrate—silicon, glass, polymers, metals and ceramics. The substrates can be planar and non-planar surfaces. The printing process is typically followed by a thermal treatment, such as in a furnace or with a laser, to achieve dense functionalized structures.

The use of additive printing processes permits the material set in a given layer to vary. Traditional PCB and circuit fabrication methods take sheets of material and stack them up, laminate, and/or drill. The materials in each layer are limited to the materials in a particular sheet. Additive printing technologies permit a wide variety of materials to be applied on a layer with a registration relative to the features of the previous layer. Selective addition of conductive, non-conductive, or semi-conductive materials at precise locations to create a desired effect has the major advantages in tuning impedance or adding electrical function on a given layer. Tuning performance on a layer by layer basis relative to the previous layer can greatly enhance electrical performance.

The present method and apparatus can permit dramatic simplification of the contact members and the substrate of the socket housing. The preferably featureless contact members reduce parasitic effects of additional metal features normally present for contact member retention. The present method and apparatus can be compatible with existing high volume manufacturing techniques. Adding functions to the socket housing permits reductions in the cost and complexity of the IC package and/or the PCB.

In another embodiment, mechanical decoupling features are added to the contact member retention structure. The interconnect assembly can be configured to electrically and mechanically couple to contact pads on the PCB, thereby reducing cost and eliminating at least one reflow cycle that can warp or damage the substrate.

The interconnect assembly can be configured with conductive traces that reduce or redistribute the terminal pitch, without the addition of an interposer or daughter substrate. Grounding schemes, shielding, electrical devices, and power planes can be added to the interconnect assembly, reducing the number of connections to the PCB and relieving routing constraints while increasing performance.

Another embodiment of the interconnect assembly may include a substrate with a plurality of through holes extending from a first surface to a second surface. Pluralities of discrete contact members are positioned in the plurality of through holes. The contact members include proximal ends that are accessible from the second surface, distal ends extending above the first surface, and intermediate portions engaged with an engagement region of the substrate located between the first surface and the recesses. Retention members are coupled with a portion of the proximal ends to retain the contact members to the substrate.

In another embodiment, the substrate may include a plurality of recesses in the second surface that at least partially overlap with a plurality of the through holes. The recesses preferably have a cross-sectional area greater than a cross-sectional area of the through holes. The retention members can be located in the recesses. The substrate can be a single layer or a plurality of layers. The substrate may also include additional circuitry planes.

The retention members can be made from a variety of materials with different levels of conductivity, ranging from highly conductive to non-conductive. For example, a retention member can be solder, solder paste, a conductive plug, a conductive adhesive, sintered conductive particles, or electrical plating.

In one embodiment, a layer of dielectric material is bonded to the first surface of the substrate. The layer preferably has a thickness less than a height of the distal ends of the contact members. The layer can be used to limit deflection of the distal end and to provide a barrier between adjacent contact members to prevent inadvertent contact.

In another embodiment, a plurality of conductive traces are located on at least one of the first and second surfaces of the substrate and electrically coupled to a plurality of the contact members. The conductive traces can have a pitch different than the pitch of the proximal ends of the contact members. A compliant layer can be positioned between one of the second surface and the conductive traces or between overlapping conductive traces. A flexible circuit member can be electrically coupled to the conductive traces and extend beyond a perimeter edge of the substrate to provide interconnection with other devices, such as for example a second interconnect assembly.

A plurality of electrical devices can be located on the substrate and electrically coupled to at least one contact member. The electrical devices may include, for example, a power plane, ground plane, capacitor, resistor, filters, signal or power altering and enhancing device, memory device, embedded integrated circuit, and RF antennae. In one embodiment, the electrical devices are printed on at least one of the first or second surface of the substrate. The electrical devices may be printed on the substrate using, for example, inkjet printing technology, aerosol printing technology, or other printing technology.

The present disclosure is also directed to an electrical assembly including contact pads on a first circuit member compressively engaged with distal ends of the contact members, and contact pads on a second circuit member bonded to one or more of the retention members or the proximal ends of the contact members. The first and second circuit members can be, for example, a dielectric layer, a printed circuit board, a flexible circuit, a bare die device, an integrated circuit device, organic or inorganic substrates, or a rigid circuit.

The present disclosure is also directed to a method of forming an interconnect assembly. A substrate may be provided with a plurality of through holes extending from a first surface to a second surface. A plurality of discrete contact members can be inserted in a plurality of the through holes. The contact members can include proximal ends that are accessible from the second surface, distal ends extending above the first surface, and intermediate portions engaged with an engagement region of the substrate located between the first surface and the recesses. A retention member is engaged with a plurality of the proximal ends to retain the contact members to the substrate. A plurality of recesses is optionally located in the second surface of the substrate that at least partially overlaps with a plurality of the through holes. The retention members can be located in the recesses.

### BRIEF DESCRIPTION OF THE SEVERAL VIEWS OF THE DRAWING

FIG. 1A is a cross-sectional view of an interconnect assembly in accordance with an embodiment of the present disclosure.

FIG. 1B is a cross-sectional view of an interconnect assembly with a multi-layered substrate in accordance with another embodiment of the present disclosure.

FIG. 1C is a cross-sectional view of an interconnect assembly in accordance with another embodiment of the present disclosure.

FIG. 2 is a cross-sectional view of an interconnect assembly with a solder ball electrically coupled to a retention member in accordance with another embodiment of the present disclosure.

FIG. 3 is a cross-sectional view of an interconnect assembly with a proximal end of a contact member extending into a solder ball in accordance with another embodiment of the present disclosure.

FIG. 4 is a cross-sectional view of an interconnect assembly with a dielectric material located between a substrate and a retention member in accordance with another embodiment of the present disclosure.

FIG. 5 is a cross-sectional view of an interconnect assembly with a dielectric material located on a first surface of a substrate in accordance with another embodiment of the present disclosure.

FIG. 6 is a cross-sectional view of an interconnect assembly with a proximal end of a contact member extending above a substrate in accordance with another embodiment of the present disclosure.

FIG. 7 is a cross-sectional view of an interconnect assembly with a retention member extending above a substrate in accordance with another embodiment of the present disclosure.

FIGS. 8 and 9 are cross-sectional views of alternate embodiments of interconnect assemblies with conductive traces on a substrate in accordance with another embodiment of the present disclosure.

FIGS. 10 and 11 are cross-sectional views of alternate embodiments of the interconnect assemblies of FIGS. 8 and 9 with conductive traces supported by a compliant layer in accordance with other embodiments of the present disclosure.

FIG. 12 is a cross-sectional view of an interconnect assembly with conductive traces electrically coupling a plurality of contact members to a point in accordance with another embodiment of the present disclosure.

FIG. 13 is a cross-sectional view of an interconnect assembly with conductive traces electrically coupling a plurality of contact members to location external to the substrate in accordance with another embodiment of the present disclosure.

FIG. 14 is a cross-sectional view of two interconnect assemblies electrically coupled by conductive traces in accordance with another embodiment of the present disclosure.

FIGS. 15 and 16 are cross-sectional views of interconnect assemblies including other electrical devices in accordance with other embodiments of the present disclosure.

FIG. 17 is a cross-sectional view of an interconnect assembly with retention tabs on contact members in accordance with another embodiment of the present disclosure.

FIG. 18 is a cross-sectional view of an interconnect assembly with capacitive coupling features in accordance with another embodiment of the present disclosure.

### DETAILED DESCRIPTION OF THE INVENTION

An interconnect assembly, according to the present disclosure, may permit fine contact-to-contact spacing (pitch) on the order of less than 1.0 millimeter (1×10⁻³ meter), and more preferably a pitch of less than about 0.7 millimeter, and most preferably a pitch of less than about 0.4 millimeter. Such fine pitch interconnect assemblies are especially useful for communications, wireless, and memory devices. The disclosed low cost, high signal performance interconnect assemblies, which have low profiles and can be soldered to the system PC board, are particularly useful for desktop and mobile PC applications.

The disclosed interconnect assemblies may permit IC devices to be installed and uninstalled without the need to reflow solder. The solder-free electrical connection of the IC devices is environmentally friendly.

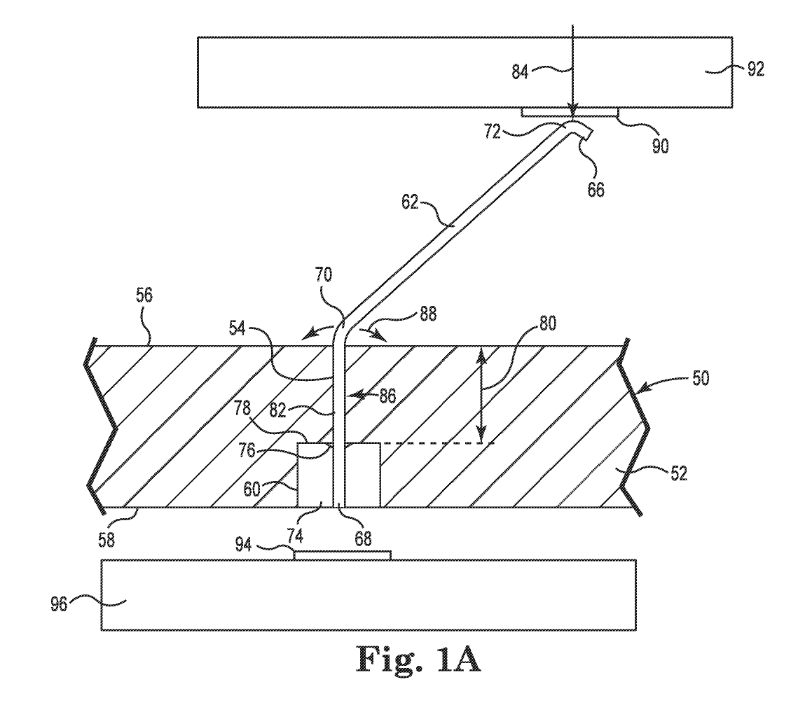

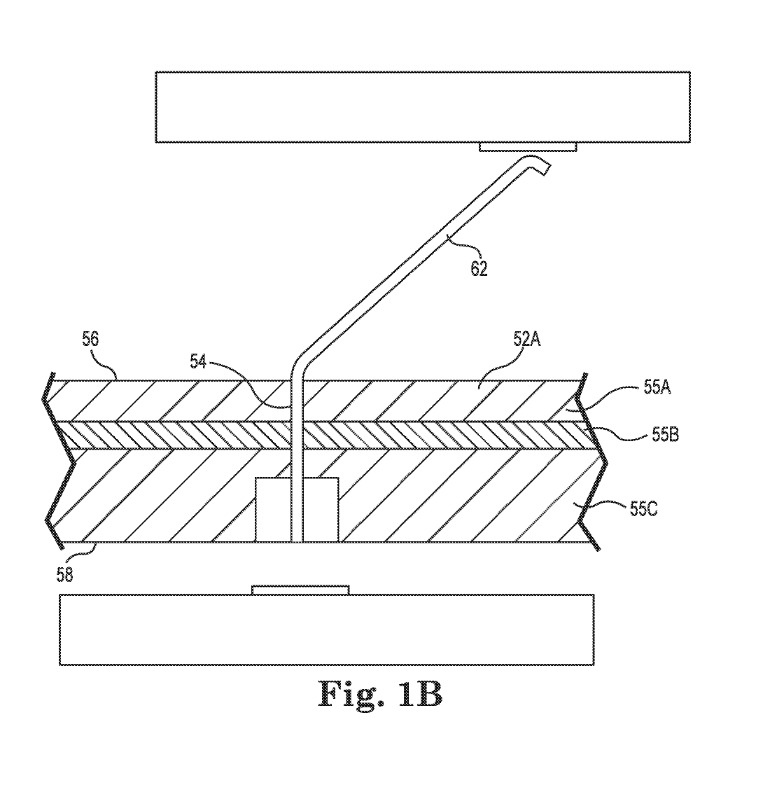

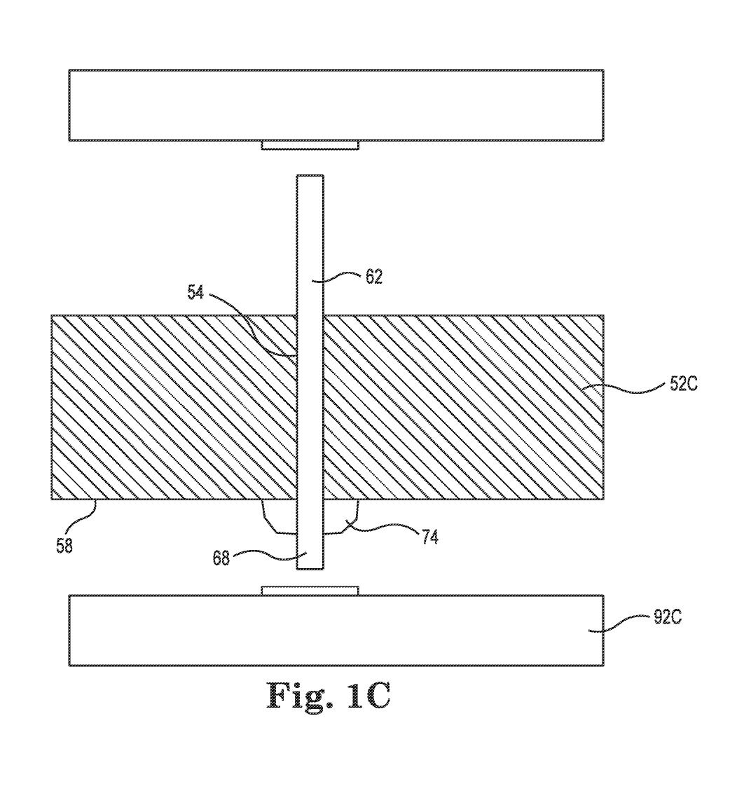

FIG. 1A is a side cross-sectional view of a portion of an interconnect assembly 50 in accordance with an embodiment of the present disclosure. A substrate 52 can include an array of through holes 54 that extend from a first surface 56 to a second surface 58. A recess 60 is formed in the second surface 58 that overlaps with the through hole 54. In one embodiment, the substrate 52 is the bottom of a socket housing adapted to receive an IC device. Although the substrate 52 is illustrated as a generally planar structure, an interconnect assembly according to the present disclosure may include one or more recesses for receiving IC devices and a cover assembly for retaining the IC devices to the substrate 52, such as disclosed in U.S. Pat. Nos. 7,101,210 (Lin et al.); 6,971,902 (Taylor et al.); 6,758,691 (McHugh et al.); 6,461,183 (Ohkita et al.); and 5,161,983 (Ohno et al.), which are hereby incorporated by reference.

The substrate 52 may be preferably constructed of any of a number of dielectric materials that are currently used to make sockets, semiconductor packaging, and PCBs. Examples may include UV stabilized tetrafunctional epoxy resin systems referred to as Flame Retardant 4 (FR-4); bismaleimide-triazine thermoset epoxy resins referred to as BT-Epoxy or BT Resin; and liquid crystal polymers (LCPs), which are polyester polymers that are extremely unreactive, inert and resistant to fire. Other suitable plastics include phenolics, polyesters, and Ryton® available from Phillips Petroleum Company.

The substrate 52 may also be constructed from metal, such as aluminum, copper, or alloys thereof, with a non-conductive surface, such as an anodized surface. In another embodiment, a metal substrate can be overmolded with a dielectric polymeric material. For example, a copper substrate may be placed in a mold and plastic may be injected around it.

In embodiments where the substrate 52 is a coated metal, the substrate 52 can be grounded to the electrical system, thus providing a controlled impedance environment. Some of the contact members 62 can be grounded by permitting them to contact an uncoated surface of the metal housing.

The substrate 52 may also include stiffening layers, such as metal, ceramic, or alternate filled resins, to be added to maintain flatness where a molded or machined part might warp. The substrate 52 may also be multi-layered (having a plurality of discrete layers), as shown in FIG. 1B and discussed below with reference to the same.

A plurality of discrete contact members 62 may be inserted into the through holes 54. In the illustrated embodiment, the contact members 62 are simple cantilever beams without any retention features. The contact members 62 preferably have a generally uniform cross section 64 from the distal end 66 to the proximal end 68. As used herein, “uniform contact member” refers to an elongate conductive element with a substantially uniform cross-sectional shape along its entire length. The cross-sectional shape can be rectangular, square, circular, triangular, or a variety of other shapes. In another embodiment, contact members 62 with a variety of features are inserted into the through holes 54 and processed as discussed herein. The contact members 62 are preferably constructed of copper or similar metallic materials such as phosphor bronze or beryllium-copper. The contact members are preferably plated with a corrosion resistant metallic material such as nickel, gold, silver, palladium, or multiple layers thereof. In some embodiments the contact members are encapsulated except the distal and proximal ends. Examples of suitable encapsulating materials include Sylgard® available from Dow Corning Silicone of Midland, Mich. and Master Sil 713 available from Master Bond Silicone of Hackensack, N.J. Suitable contact members are disclosed in U.S. Pat. Nos. 6,247,938 (Rathburn) and 6,461,183 (Ohkita et al.), which are hereby incorporated by reference.

The contact members 62 can be deposited into the through holes 54 using a variety of techniques, such as for example stitching or vibratory techniques. In one embodiment, the contact members 62 are press-fit into the through holes 54. A post insertion solder mask (as done on PCBs and IC packages) can also be added to the recesses 60 to improve solder deposit formation and wick prevention.

In one embodiment, a bend 70 limits the depth of insertion of the contact members 62 into the substrate 52 and fixes the location of a proximal end 68 relative to the second surface 58. The bend 70 also permits a distal end 66 to flex when coupled to contact pad 90 on first circuit member 92. In one embodiment, distal ends 66 of the contact members 62 are held in a fixture until proximal ends 68 are secured to the substrate 52 by a retention member 74.

An intermediate portion 82 of the contact member 62 is engaged with an engagement region 86 of the substrate 52 located between the first surface 56 and the recess 60. In one embodiment, the intermediate portion 82 forms a friction fit with the engagement region 86. Thickness 80 of the engagement region 86 provides sufficient surface area to limit rotation of the contact member 62 relative to the substrate 52 in any direction, including rotation 88 about the longitudinal access of the intermediate portion 82. In a preferred embodiment, the engagement region 86 of the substrate 52 limits rotation 88 to less than about 1 degree to about 3 degrees, and more preferably less than about 0.5 degrees.

The surface area of the engagement region 86 is preferably sufficient to counteract a force 84 applied to proximal end 66, without leading to plastic deformation of the contact member 62. The surface area of the engagement region 86 between the proximal end 68 and the through hole 54 also provides friction that aids in retaining the contact member 54 in the substrate 52.

A bend 72 near distal end 66 is optionally provided to enhance coupling with the contact pads 90 on the first circuit member 92. The contact members 62 may have a variety of shapes, such as reversing the bend 72 or basic vertical structures. Proximal end 68 can be electrically coupled to contact pads 94 on a second circuit member 96 using a variety of techniques, including solder, pressure, and the like. As used herein, the term “circuit member” refers to, for example, a packaged integrated circuit device, an unpackaged integrated circuit device, a printed circuit board, a flexible circuit, a bare-die device, an organic or inorganic substrate, a rigid circuit, or any other device capable of carrying electrical current.

With contact members 62 inserted, the substrate 52 is inverted to expose the proximal ends 68 located within the recess 60. The proximal ends 68, the recesses 60 and the second surface 58 can then be subjected to additional processing as discussed in the various embodiments detailed below. In one embodiment, the force 84 is applied to the contact members 62 during subsequent processing so as to minimize stresses in the assembly during engagement with IC 92. In these subsequent embodiments, the substrate 52 and contact member 62 are generally configured as discussed in connection with FIG. 1A, although some variation may occur to accommodate certain aspects of the particular embodiment.

In the embodiment of FIG. 1A, retention member 74 is formed in the recess 60 to provide contact retention and as a solder attachment point that will control the wetting region of the molten solder. In one embodiment, the recesses 60 are substantially filled with a conductive material, such as for example, solder, solder paste, a conductive plug, conductive adhesive, or conductive plating. In another embodiment, the retention member 74 is a mixture including conductive particles that are sintered in situ within the recess 60.

The retention member 74 is preferably conductive and preferably bonds well to solder. In another embodiment, the retention member 74 can be made from a variety of materials with different levels of conductivity, ranging from highly conductive to non-conductive.

The retention member 74 is optionally deposited in the recesses 60 before the contact members 62 are inserted into the substrate 52. The contact members 62 are plugged into the retention member 74. The retention member 74 preferably has sufficient adhesive properties to retain the contact members 62 in the substrate 52 during subsequent processing.

In yet another embodiment, the retention member 74 is formed from a conductive ink, which can be optionally deposited into the recesses 60 using various printing technologies, such as for example inkjet printing technology, aerosol printing technology, or other printing technology. A printer may deposit droplets of ink (e.g. material) using, for example a printing head.

The availability of printable silicon inks provides the ability to print electrical devices and features, such as disclosed in U.S. Pat. Nos. 7,485,345 (Renn et al.); 7,382,363 (Albert et al.); 7,148,128 (Jacobson); 6,967,640 (Albert et al.); 6,825,829 (Albert et al.); 6,750,473 (Amundson et al.); 6,652,075 (Jacobson); 6,639,578 (Comiskey et al.); 6,545,291 (Amundson et al.); 6,521,489 (Duthaler et al.); 6,459,418 (Comiskey et al.); 6,422,687 (Jacobson); 6,413,790 (Duthaler et al.); 6,312,971 (Amundson et al.); 6,252,564 (Albert et al.); 6,177,921 (Comiskey et al.); 6,120,588 (Jacobson); 6,118,426 (Albert et al.); and U.S. Pat. Publication No. 2008/0008822 (Kowalski et al.), which are hereby incorporated by reference.

Various methods for maskless deposition of electronic materials and forming electrical devices and features may also be used, such as disclosed in U.S. Pat. Nos. 7,485,345 (Renn et al.); 6,825,829 (Albert at al.); and U.S. Pat. Publication No. 2008/0008822 (Kowalski et al.), which are hereby incorporated by reference. Inkjet printing technology, aerosol printing technology, and other printing technologies are examples of maskless deposition which can be used to deposit material to form electrical devices and features.

Printing processes are preferably used to fabricate various functional structures, such as conductive paths and electrical devices, without the use of masks or resists. Features down to about 10 microns can be directly written in a wide variety of functional inks, including metals, ceramics, polymers and adhesives, on virtually any substrate—silicon, glass, polymers, metals and ceramics. The substrates can be planar and non-planar surfaces. The printing process is typically followed by a thermal treatment, such as in a furnace or with a laser, to achieve dense functionalized structures.

U.S. Pat. Nos. 6,506,438 (Duthaler et al.) and 6,750,473 (Amundson et al.), which are hereby incorporated by reference, teach using inkjet printing to make various electrical devices, such as, resistors, capacitors, diodes, inductors (or elements which may be used in radio applications or magnetic or electric field transmission of power or data), semiconductor logic elements, electro-optical elements, transistor (including, light emitting, light sensing or solar cell elements, field effect transistor, top gate structures), and the like.

U.S. Pat. Nos. 7,674,671 (Renn et al.); 7,658,163 (Renn et al.); 7,485,345 (Renn et al.); 7,045,015 (Renn et al.); and 6,823,124 (Renn et al.), which are hereby incorporated by reference, teach using aerosol printing to create various electrical devices and features.

Printing of electronically active inks can be done on a large class of substrates, without the requirements of standard vacuum processing or etching. The inks may incorporate mechanical, electrical or other properties, such as, conducting, insulating, resistive, magnetic, semiconductive, light modulating, piezoelectric, spin, optoelectronic, thermoelectric or radio frequency.

A plurality of ink drops are dispensed from the print head directly to a substrate or on an intermediate transfer member. The transfer member can be a planar or non-planar structure, such as a drum. The surface of the transfer member can be coated with a non-sticking layer, such as silicone, silicone rubber, or teflon.

The ink (also referred to as function inks) can include conductive materials, semi-conductive materials (e.g., p-type and n-type semiconducting materials), metallic material, insulating materials, and/or release materials. The ink pattern can be deposited in precise locations on a substrate to create fine lines having a width smaller than 10 microns, with precisely controlled spaces between the lines. For example, the ink drops form an ink pattern corresponding to portions of a transistor, such as a source electrode, a drain electrode, a dielectric layer, a semiconductor layer, or a gate electrode.

The substrate can be an insulating polymer, such as polyethylene terephthalate (PET), polyester, polyethersulphone (PES), polyimide film (e.g. Kapton, available from Dupont located in Wilminton, Del.; Upilex available from Ube Corporation located in Japan), or polycarbonate. Alternatively, the substrate can be made of an insulator such as undoped silicon, glass, or a plastic material. The substrate can also be patterned to serve as an electrode. The substrate can further be a metal foil insulated from the gate electrode by a non-conducting material. The substrate can also be a woven material or paper, planarized or otherwise modified on at least one surface by a polymeric or other coating to accept the other structures.

Electrodes can be printed with metals, such as aluminum or gold, or conductive polymers, such as polythiophene or polyaniline. The electrodes may also include a printed conductor, such as a polymer film comprising metal particles, such as silver or nickel, a printed conductor comprising a polymer film containing graphite or some other conductive carbon material, or a conductive oxide such as tin oxide or indium tin oxide.

Dielectric layers can be printed with a silicon dioxide layer, an insulating polymer, such as polyimide and its derivatives, poly-vinyl phenol, polymethylmethacrylate, polyvinyldenedifluoride, an inorganic oxide, such as metal oxide, an inorganic nitride such as silicon nitride, or an inorganic/organic composite material such as an organic-substituted silicon oxide, or a sol-gel organosilicon glass. Dielectric layers can also include a bicylcobutene derivative (BCB) available from Dow Chemical (Midland, Mich.), spin-on glass, or dispersions of dielectric colloid materials in a binder or solvent.

Semiconductor layers can be printed with polymeric semiconductors, such as, polythiophene, poly(3-alkyl)thiophenes, alkyl-substituted oligothiophene, polythienylenevinylene, poly(para-phenylenevinylene) and doped versions of these polymers. An example of suitable oligomeric semiconductor is alpha-hexathienylene. Horowitz, Organic Field-Effect Transistors, Adv. Mater., 10, No. 5, p. 365 (1998) describes the use of unsubstituted and alkyl-substituted oligothiophenes in transistors. A field effect transistor made with regioregular poly(3-hexylthiophene) as the semiconductor layer is described in Bao et al., Soluble and Processable Regioregular Poly(3-hexylthiophene) for Thin Film Field-Effect Transistor Applications with High Mobility, Appl. Phys. Lett. 69 (26), p. 4108 (December 1996). A field effect transistor made with a-hexathienylene is described in U.S. Pat. No. 5,659,181 (Bridenbaugh et al.), which is incorporated herein by reference.

A protective layer can optionally be printed onto the electrical devices and features. The protective layer can be an aluminum film, a metal oxide coating, a polymeric film, or a combination thereof.

Organic semiconductors can be printed using suitable carbon-based compounds, such as, pentacene, phthalocyanine, benzodithiophene, buckminsterfullerene or other fullerene derivatives, tetracyanonaphthoquinone, and tetrakisimethylanimoethylene. The materials provided above for forming the substrate, the dielectric layer, the electrodes, or the semiconductor layer are exemplary only. Other suitable materials known to those skilled in the art having properties similar to those described above can be used in accordance with the present invention.

An inkjet print head, or other print head, preferably includes a plurality of orifices for dispensing one or more fluids onto a desired media, such as for example, a conducting fluid solution, a semiconducting fluid solution, an insulating fluid solution, and a precursor material to facilitate subsequent deposition. The precursor material can be surface active agents, such as octadecyltrichlorosilane (OTS).

Alternatively, a separate print head can be used for each fluid solution. The print head nozzles can be held at different potentials to aid in atomization and imparting a charge to the droplets, such as disclosed in U.S. Pat. No. 7,148,128 (Jacobson), which is hereby incorporated by reference. Alternate print heads are disclosed in U.S. Pat. No. 6,626,526 (Ueki et al.), and U.S. Pat. Publication Nos. 2006/0044357 (Andersen et al.) and 2009/0061089 (King et al.), which are hereby incorporated by reference.

The print head preferably uses a pulse-on-demand method, and can employ one of the following methods to dispense the ink drops: piezoelectric, magnetostrictive, electromechanical, electropneumatic, electrostatic, rapid ink heating, magnetohydrodynamic, or any other technique well known to those skilled in the art. The deposited ink patterns typically undergo a curing step or another processing step before subsequent layers are applied.

The use of additive printing processes permits the material set in a given layer to vary. Traditional PCB and circuit fabrication methods take sheets of material and stack them up, laminate, and/or drill. The materials in each layer are limited to the materials in a particular sheet. Additive printing technologies permit a wide variety of materials to be applied on a layer with a registration relative to the features of the previous layer. Selective addition of conductive, non-conductive, or semi-conductive materials at precise locations to create a desired effect has the major advantages in tuning impedance or adding electrical function on a given layer. Tuning performance on a layer by layer basis relative to the previous layer greatly enhances electrical performance.

While inkjet printing is preferred, the term “printing” is intended to include all forms of printing and coating, including: premetered coating such as patch die coating, slot or extrusion coating, slide or cascade coating, and curtain coating; roll coating such as knife over roll coating, forward and reverse roll coating; gravure coating; dip coating; spray coating; meniscus coating; spin coating; brush coating; air knife coating; screen printing processes; electrostatic printing processes; thermal printing processes; aerosol printing processes; and other similar techniques.

With each pass of the printing heads, additional ink is applied at a desired location on substrate 52, in this case in recess 60. In other embodiments, other components of the interconnect assembly 50 may be applied using printing technology, such as for example inkjet printing technology, aerosol printing technology, or other printing technology, including three-dimensional components extending away or above the first and second surfaces 56, 58. In such cases, the substrate 52 may rest or be secured to a base during the printing process. With each pass of the printing heads, the base on which the substrate 52 rests moves down a notch. In this way, little by little the component takes shape. Components may also be printed on a removable “scaffold,” which provides support and/or a desired component shape. In some embodiments the conductive ink is subsequently sintered.

In another embodiment, a sealing material 76 is applied to the intersection of the base 78 of the retention member 74 with the proximal end 68 to prevent solder from wicking along the contact members 62. The sealing member 76 may also be a mechanism for retaining the contact member 62 to the substrate 52. The sealing member 76 may be deposited using various printing technologies, including inkjet printing technology, aerosol printing technology, or other printing technology as was previously described.

In another embodiment, the portion of the contact members 62 located above and below the surfaces 56, 58 can be bent, peened, coined or otherwise plastically deformed during or after insertion into the substrate 52. For example, proximal end 68 can be plastically deformed to retain the contact member 62 in the substrate 52.

Subsequent processing of the various interconnect assemblies disclosed herein can be done with conventional techniques, such as for example screen printing for features larger than about 100 micrometers and thin film and etching methods for features smaller than about 100 micrometers. Other subtractive methods to attain fine feature sizes include the use of photo-patternable pastes and laser trimming.

FIG. 1B is a cross-sectional view of an interconnect assembly with a multi-layered substrate 52A including a plurality of discrete layers 55A, 55B, 55C (collectively “55”). The layers 55 can be etched or ablated and stacked without the need for expensive mold tooling. The layers 55 can create features that have a much larger aspect ratio than typically possible with molding or machining. The layers 55 also permit the creation of internal features, undercuts, or cavities that are difficult or typically not possible to make using conventional molding or machining techniques, referred to herein as a “non-moldable feature.” The substrate 52A may also permit stiffening layers, such as metal, ceramic, or alternate filled resins, to be added to maintain flatness where a molded or machined part might warp. The layers 55 can be selectively bonded or non-bonded to provide contiguous material or releasable layers. As used herein, “bond” or “bonding” refers to, for example, adhesive bonding, solvent bonding, ultrasonic welding, thermal bonding, or any other techniques suitable for attaching adjacent layers of the housing.

One of the layers 55 can optionally be an additional circuitry plane, such as for example a ground plane, a power plane, an electrical connection to other circuit members, a dielectric layer, a printed circuit board, a flexible circuit, a bare die device, an integrated circuit device, organic or inorganic substrates, or a rigid circuit. The additional circuitry plane can also be formed on one of the surfaces 56, 58. In another embodiment, one of the layers 55 can be a high friction material that aids in retaining contact members 62 in the through hole 54. As previously described, the use of additive printing processes permits a wide variety of materials to be applied on a layer with a registration relative to the features of the previous layer. Selective addition of conductive, non-conductive, or semi-conductive materials at precise locations to create a desired effect can offer a variety of advantages and can improve electrical performance.

FIG. 1C is a cross-sectional view of an interconnect assembly in accordance with another embodiment having an alternate substrate 52C without a recess in the second surface 58 overlapping the through hole 54. The proximal end 68 of the contact member 62 is accessible from the second surface 58. Any of the retention members 74 discussed above can be located at the intersection of the contact member 62 with the second surface 58. In one embodiment, fixtures and/or tooling can be used to limit the depth of insertion of the contact members 62 into the substrate 52C, such as for example locating fixture 92C in proximity to the second surface 58.

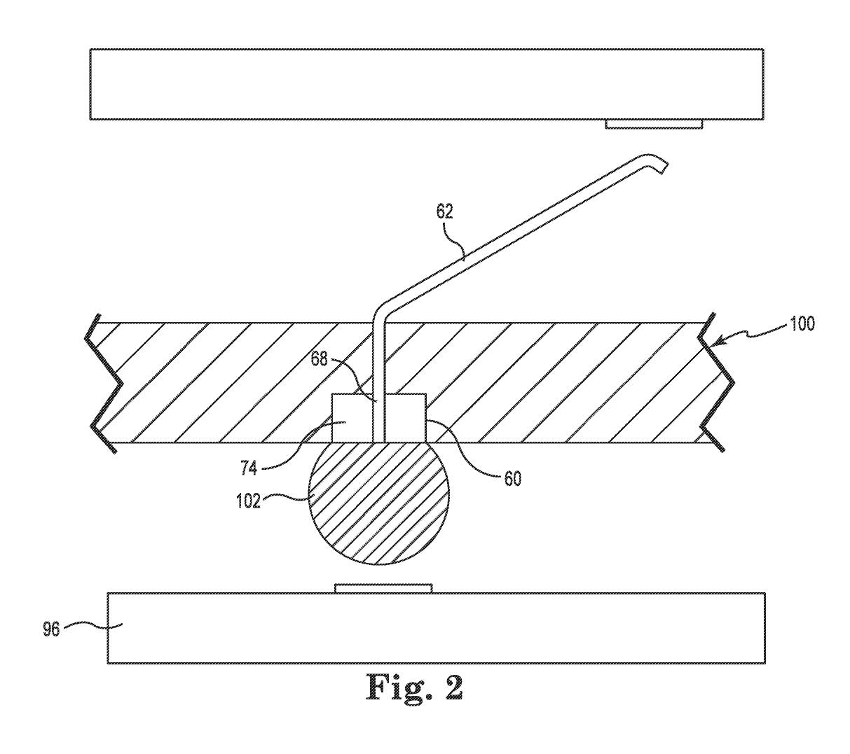

FIG. 2 is a cross-sectional view of an interconnect assembly 100 in accordance with an embodiment of the present disclosure. Solder ball 102 is added to the metalized retention member 74 in the recess 60. In one embodiment, the solder ball 102 is printed onto the proximal end 68 of the contact member 62. The solder ball 102 may be printed, for example, using inkjet printing technology, aerosol printing technology, or other printing technology. The metallization of the recess 60 provides the wetting surface and inherently minimizes wicking of solder during reflow. In the preferred embodiment, the solder ball 102 is reflowed to provide both electrical and structural attachment to the second circuit member 96.

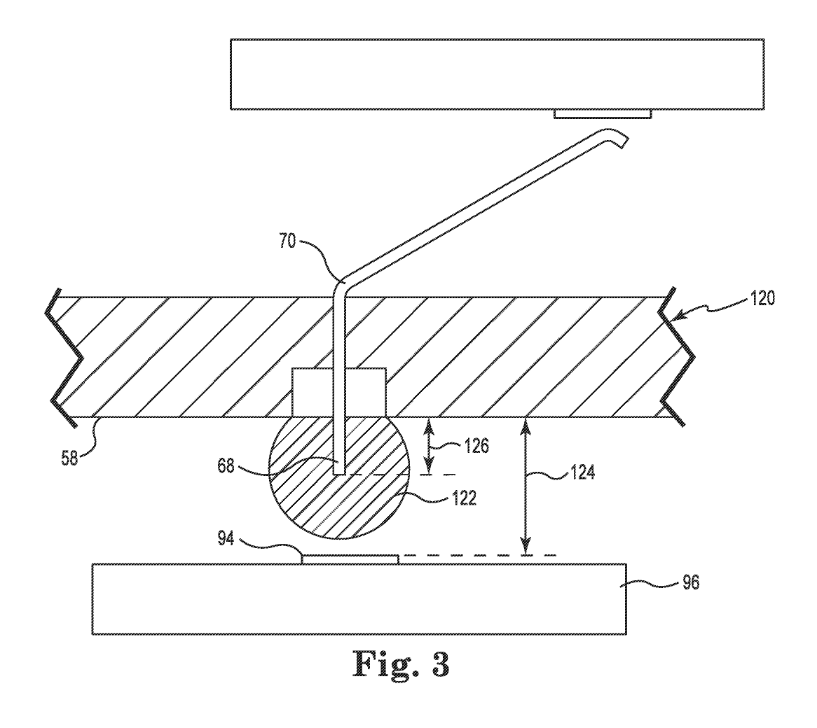

FIG. 3 is a cross-sectional view of an interconnect assembly 120 in accordance with another embodiment of the present disclosure. Bend 70 is located so that proximal end 68 of the contact member 62 extends above the second surface 58. The proximal end 68 is embedded in the solder ball 122 to improve solder joint strength and resistance to shear load. Gap 124 between the second surface 58 and the contact pad 94 on the second circuit member 96 can be controlled by height 126 of the proximal end 68 above the second surface 58 or some other mechanism.

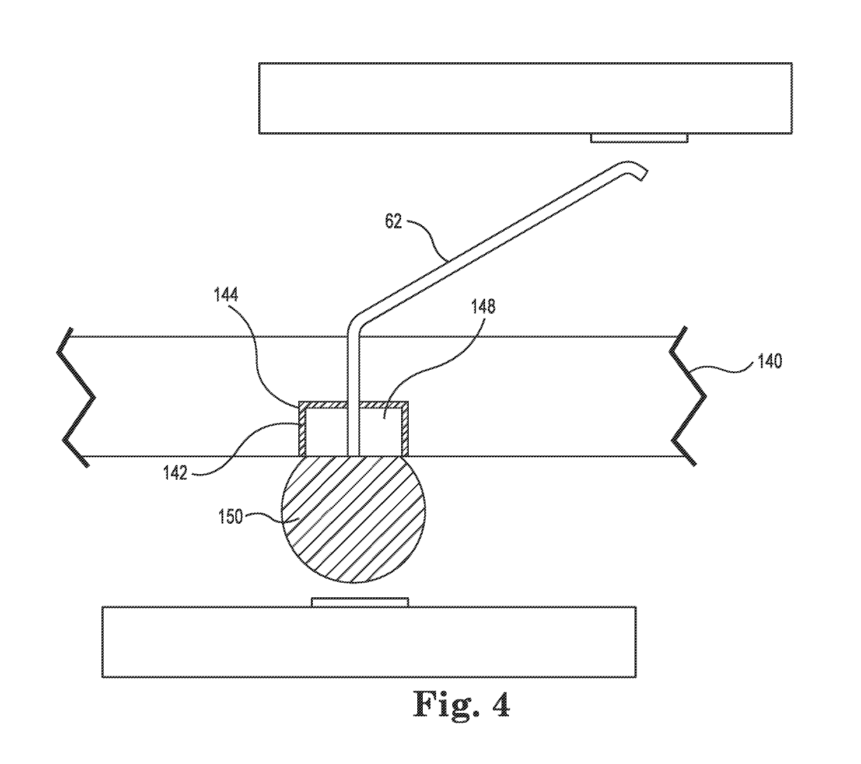

FIG. 4 is a cross-sectional view of an interconnect assembly 140 in accordance with another embodiment of the present disclosure. A compliant or dielectric material 142 is applied to interior surface of the recess 144. A conductive material 148 is then deposited in the recess 144. The compliant/dielectric material 142 decouples mechanical stress between the substrate 52 and the contact member 62 and/or the solder ball 150. The compliant/dielectric material 142 can also be used to alter impedance of the contact member 62.

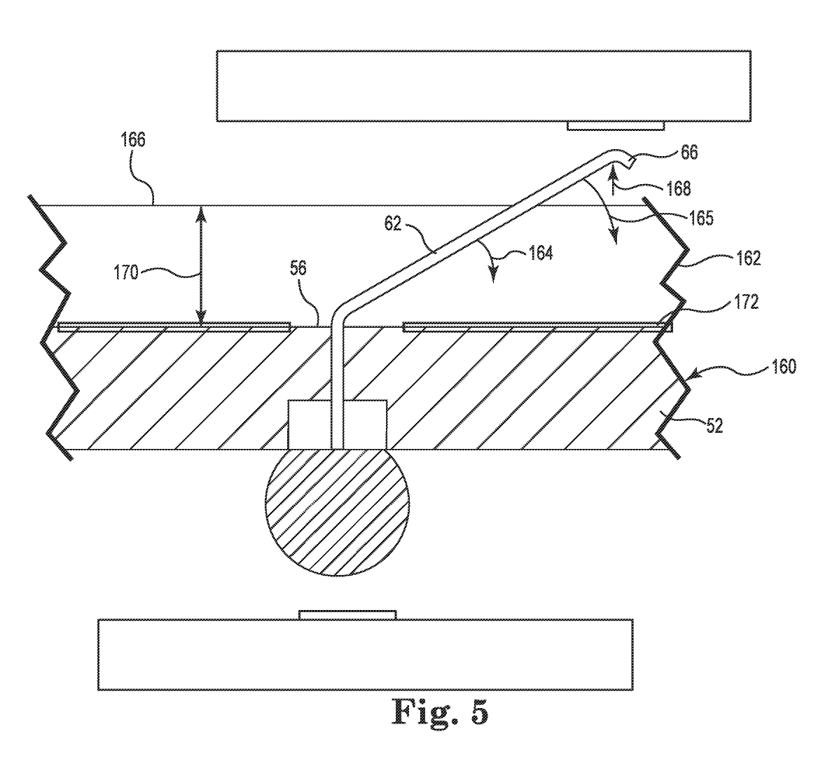

FIG. 5 is a cross-sectional view of an interconnect assembly 160 in accordance with another embodiment of the present disclosure. Layer 162 is bonded to the first surface 56 of the substrate 52 to perform a number of functions.

In one embodiment, the layer 162 protects the contact members 62 during shipping and assembly. In one embodiment, the layer 162 is formed in-situ on the first surface 56 of the substrate 52. In another embodiment, the layer 162 optionally includes slots that correspond with the locations of the proximal ends 66 of the contact members 62. The layer 162 can be used to limit deflection 164 of the distal end 66 to a single plane. The layer 162 can also provide a barrier between adjacent contact members 62 to prevent inadvertent electrical connections.

In another embodiment, the layer 162 isolates deflection 165 of the contact member 62 primarily to the distal end 66 located above top surface 166 of the layer 162. The resistance to deflection 168 of the distal end 66 can be adjusted by changing thickness 170 of the layer 162. In particular, decreasing the thickness 170 will reduce the force 168 required to deflect the distal end 66, and vice versa.

The layer 162 optionally stiffens the substrate 52 to reduce warpage during reflow. In one embodiment, layers 162 is made of materials such as BeCu, Cu, ceramic, or polymer filled ceramic that provide additional strength and thermal stability.

The layer 162 can also be designed to provide electrostatic dissipation or to reduce cross-talk between the contact members 62. An efficient way to prevent electrostatic discharge (ESD) is to construct the layer 162 from materials that are not too conductive but that will slowly conduct static charges away. These materials preferably have resistivity values in the range of 10⁵ to 10¹¹ Ohm-meters. The materials discussed above for use in the substrate 52 can also be used for the layer 162.

In another embodiment, the first surface 56 can be selectively metalized to provide electromagnetic shielding 172. In one embodiment, the shielding 172 is printed onto the first surface 56 using metallic inks. The shielding 172 may be printed using, for example, inkjet printing technology, aerosol printing technology, or other printing technology.

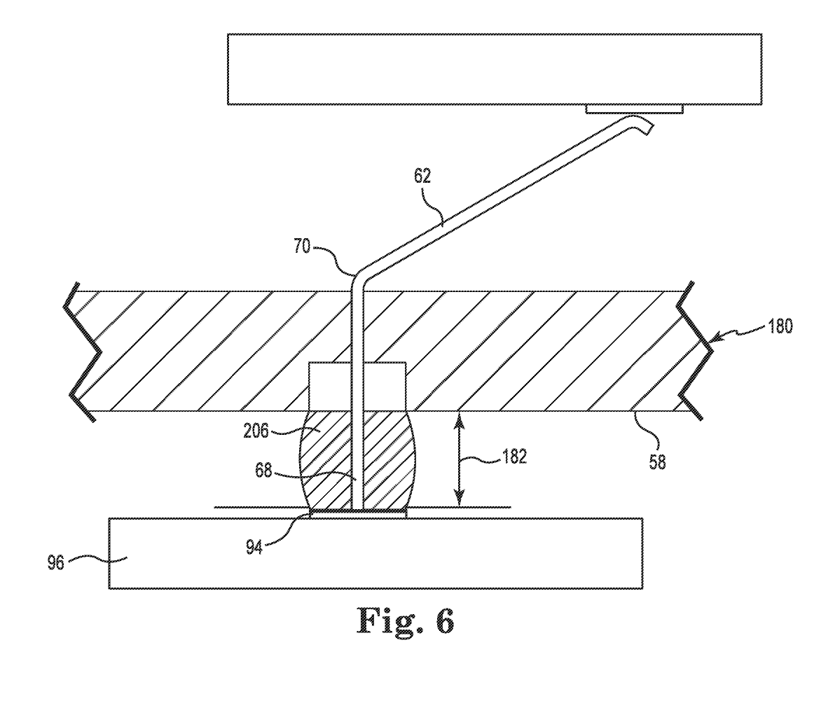

FIG. 6 is a cross-sectional view of an interconnect assembly 180 in accordance with another embodiment of the present disclosure. Bend 70 is located so that proximal end 68 of the contact member 62 acts as a standoff 182 between the second surface 58 of the interconnect assembly 180 and the contact pad 94 on the second circuit member 96. In one embodiment, solder or solder paste 206 is deposited onto contact pad 94, eliminating the solder ball as well as at least one high temperature cycle required to attach a solder ball to the interconnect assembly 180.

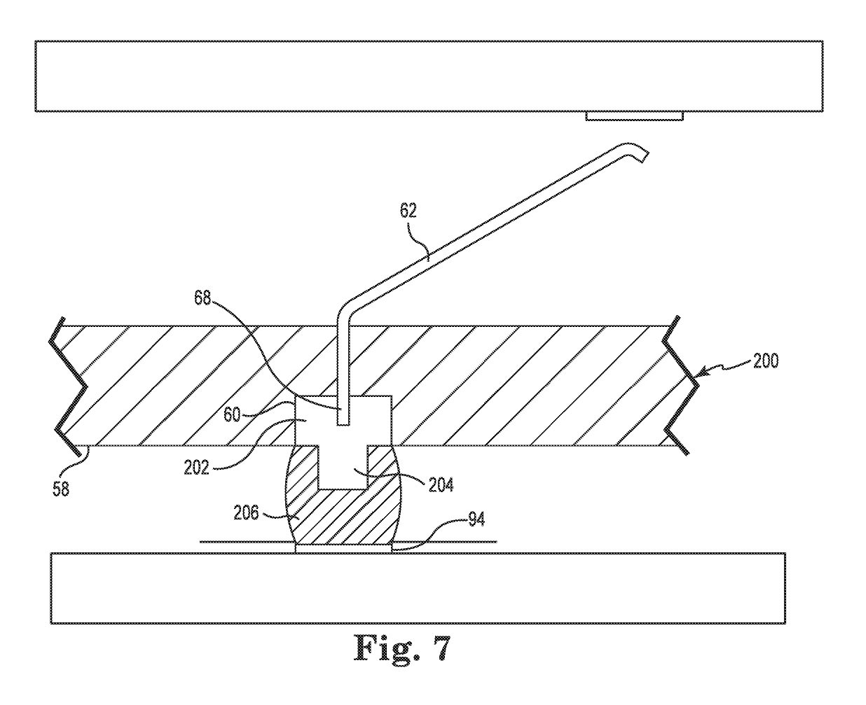

FIG. 7 is a cross-sectional view of an interconnect assembly 200 in accordance with another embodiment of the present disclosure. Conductive retention member 202 bonds to the proximal end 68 of the contact member 62 and extends above second surface 58 of the substrate 52. In the illustrated embodiment, portion 204 of the retention member 202 has a smaller cross section than the recess 60. Solder or solder paste 206 is preferably deposited onto contact pad 94, eliminating the solder ball as well as at least one high temperature cycle required to attach a solder ball to the interconnect assembly 200. In one embodiment, the metalized retention member 202 is deposited using photolithographic or printing technology, such as for example inkjet printing technology, aerosol printing technology, or other printing technology.

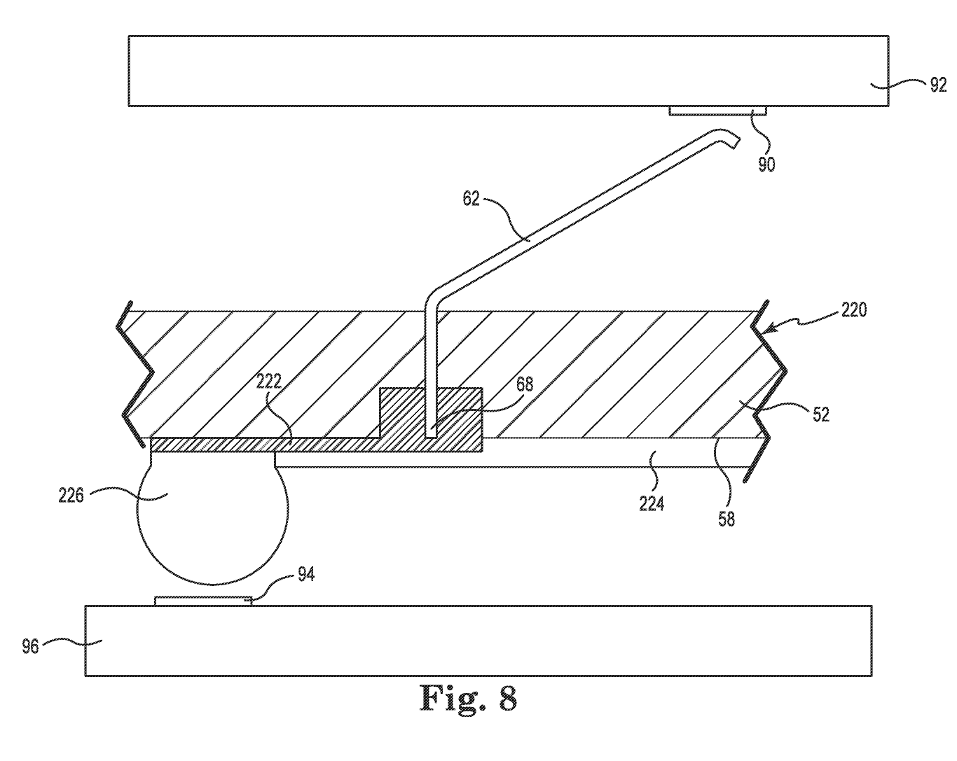

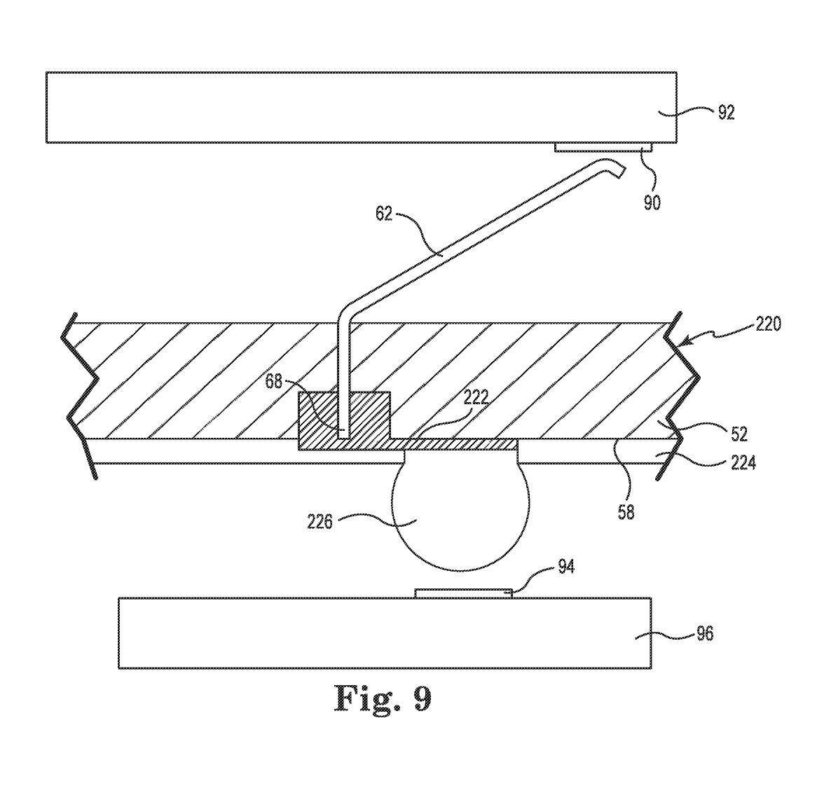

FIGS. 8 and 9 are alternate embodiments of an interconnect assembly 220 in accordance with another embodiment of the present disclosure. Conductive traces 222 can be added to the second surface 58 to create an offset or redistribution of the pitch of the contact pads 90 on the first circuit member 92 relative to the contact pads 94 on the second circuit member 96. Dielectric layer 224 is preferably deposited over the conductive traces 222.

The conductive traces 222 can be used to alter, redirect, or reduce the effective termination pitch of the first circuit member 92. The second surface 58 of the substrate 52 is treated like a printed circuit board, onto which various electrical device can be added, such as for example by inkjet printing technology, aerosol printing technology, or other printing technology. In the illustrated embodiments, the conductive traces 222 electrically couple the proximal ends 68 of the contact members 62 with solder ball 226.

The resulting circuit geometry preferably has conductive traces that have substantially rectangular cross-sectional shapes. In one embodiment, pre-formed conductive trace materials are positioned in recesses or trenches in the second surface 58 of the substrate 52. The recesses can be plated to form conductive traces with substantially rectangular cross-sectional shapes. In another embodiment, a conductive foil is pressed into at least a portion of the recesses. The conductive foil is sheared along edges of the recesses. The excess conductive foil not located in the recesses is removed and the recesses are plated to form conductive traces with substantially rectangular cross-sectional shape.

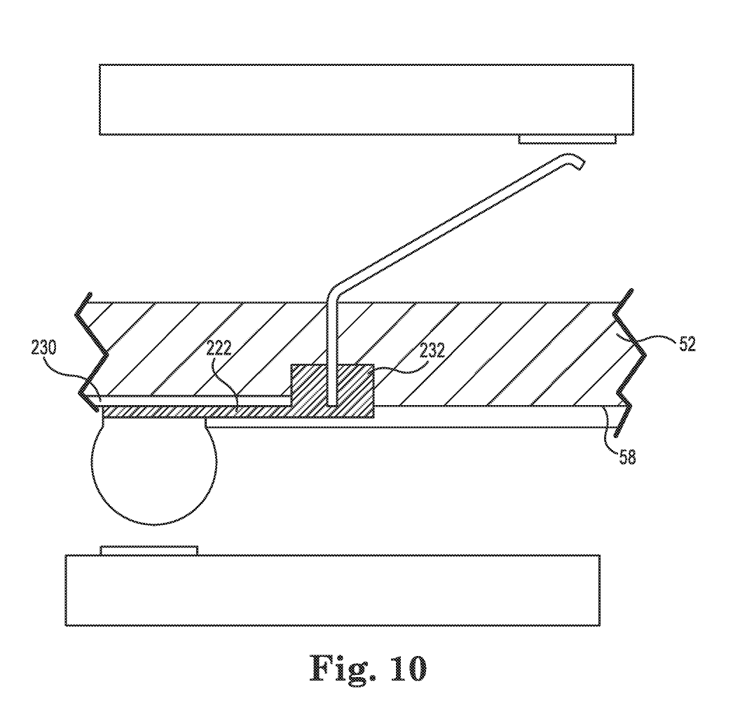

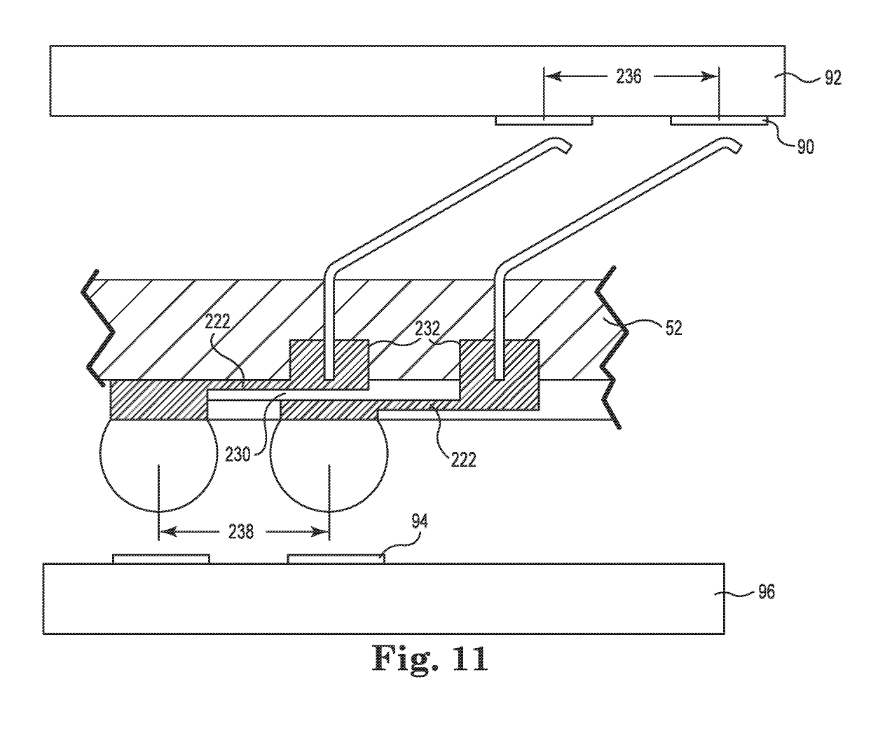

FIGS. 10 and 11 are cross sectional views of alternate embodiments of the interconnect assembly 220 of FIGS. 8 and 9. A compliant decoupling layer 230 is located between the conductive traces 222 and the second surface 58 of the substrate 52 or between adjacent conductive traces 222. The compliant decoupling layer 230 improves joint reliability and reduces internal stress. A compliant decoupling layer 230 can also be added between the metalized recess 232 and the substrate 52 to decouple thermal expansion and loading stresses. The compliant decoupling layer can be formed by inkjet printing technology, aerosol printing technology, or other printing technology. The embodiments of FIGS. 10 and 11 merge features of sockets, PCB and/or semiconductor packages. The conductive traces 222 have substantially rectangular cross-sectional shapes.

The embodiment of FIG. 11 illustrates the contact pads 90 on the first circuit member 92 having first pitch 236 and the contact pads 94 on the second circuit member 96 having second pitch 238. The first and second pitches 236, 238 can be the same or different. In the illustrated embodiment, the first pitch 236 can be modified and/or offset by the conductive traces 222.

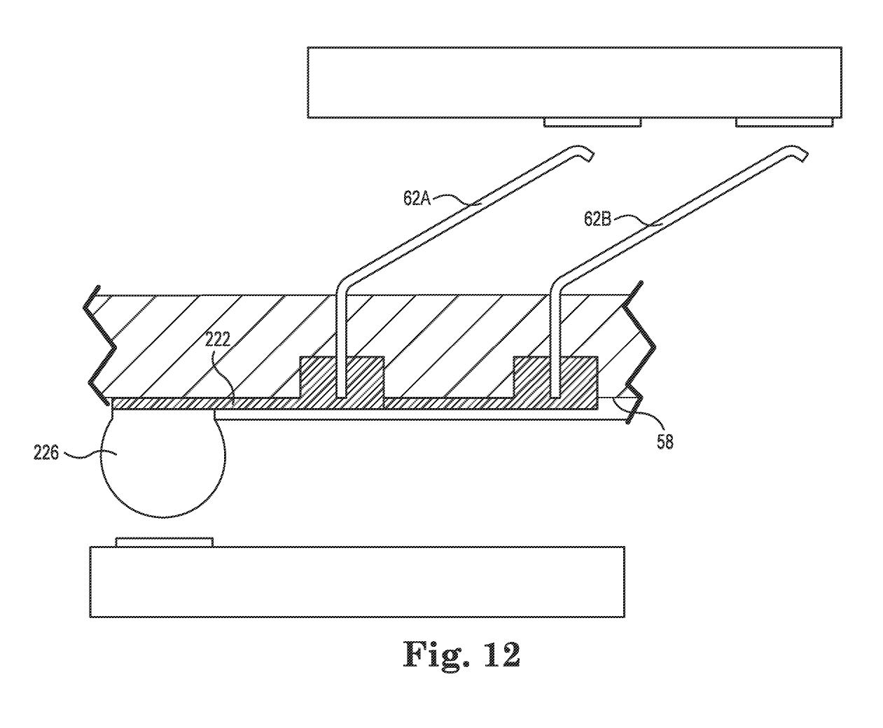

FIG. 12 is a cross-sectional view of an interconnect assembly according to another embodiment where the conductive traces 222 formed on the second surface 58 of the substrate 52 are used to create an internal ground plane, resulting in a reduction of ground connections to the second circuit member 96. Both contact members 62A and 62B are electrically coupled to a single solder ball 226 by conductive traces 222. The conductive traces 222 have substantially rectangular cross-sectional shapes.

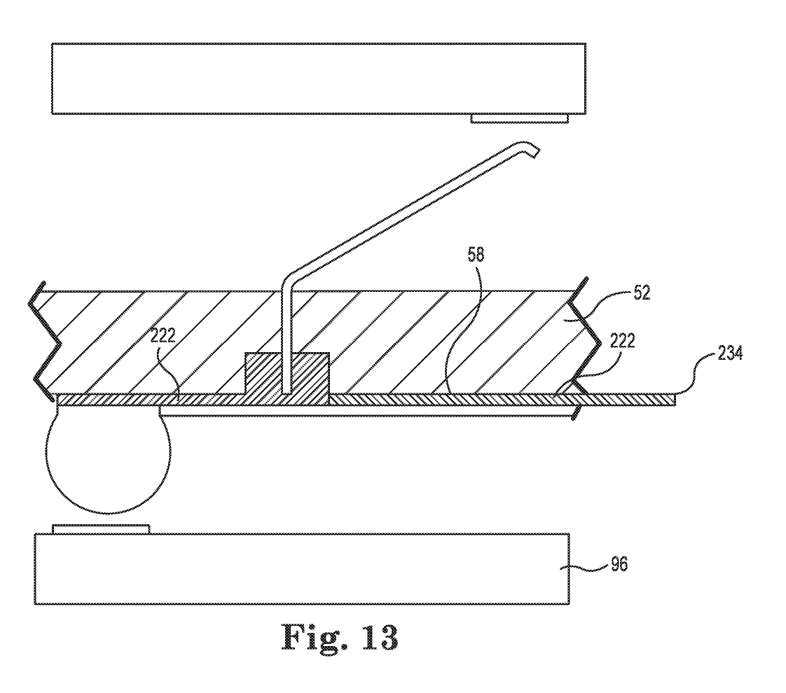

FIG. 13 is a cross-sectional view of an interconnect assembly according to another embodiment where the conductive traces 222 formed on the second surface 58 of the substrate 52 are used as a power management circuit. The conductive traces 222 can be formed by inkjet printing technology, aerosol printing technology, or other printing technology. The conductive traces 222 can deliver, condition, and manage power from an external connection 234 separate from power provided by the second circuit member 96. As illustrated, the conductive traces 222 may extend beyond a perimeter edge of the substrate to the external connection 234. The conductive traces 222 have substantially rectangular cross-sectional shapes.

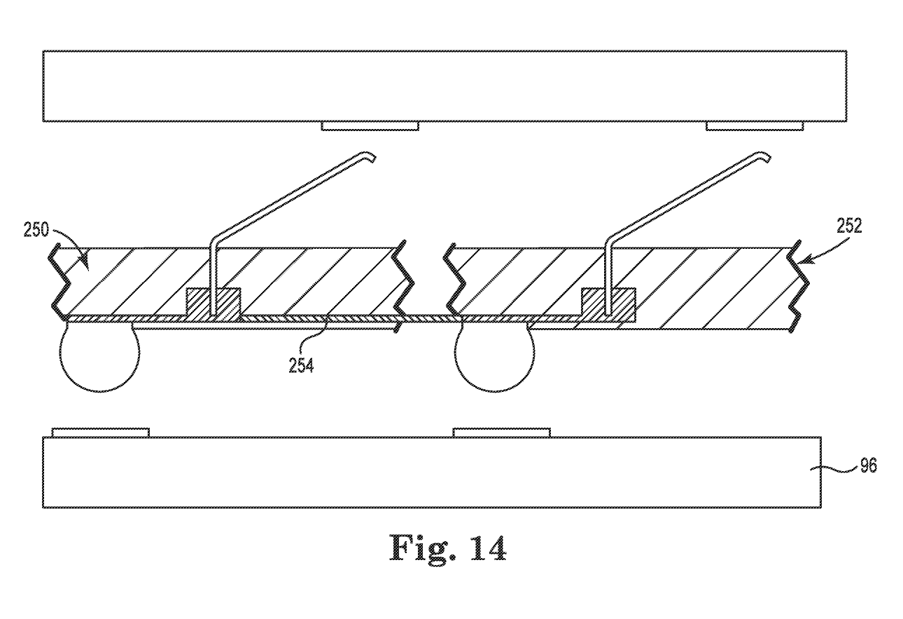

FIG. 14 is a cross-sectional view of a pair of interconnect assemblies 250, 252 coupled together in accordance with another embodiment of the present disclosure. The interconnect assemblies use conductive traces 254 to create a socket-to-socket connection external to the second circuit member 96. The second circuit may be a main PCB. In some embodiments, a direct socket-to-socket connection provides a flexible high frequency interface.

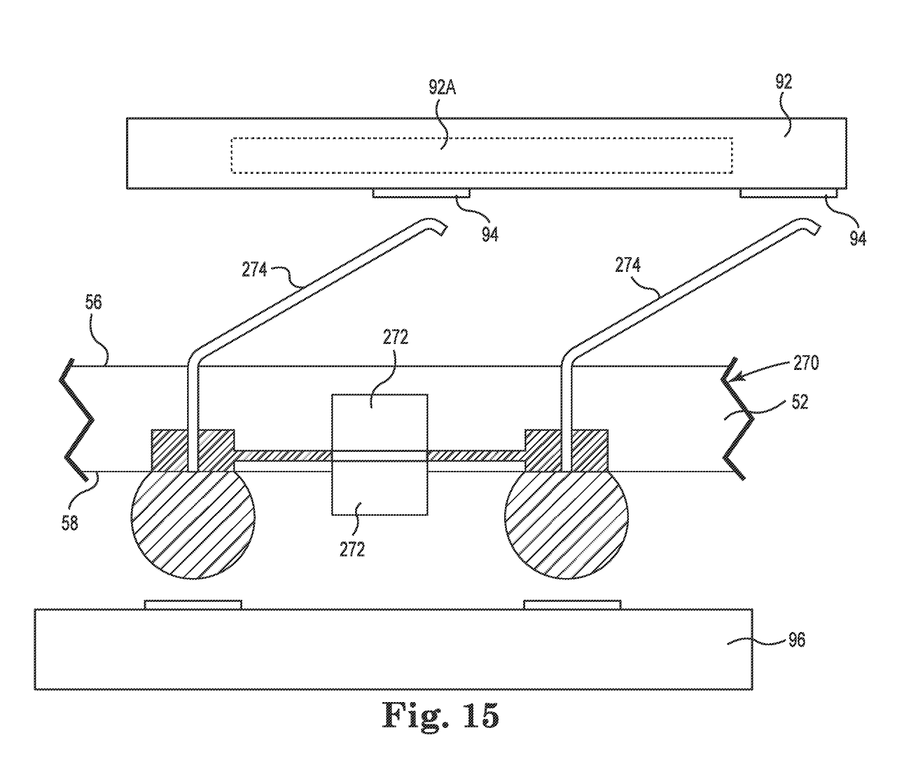

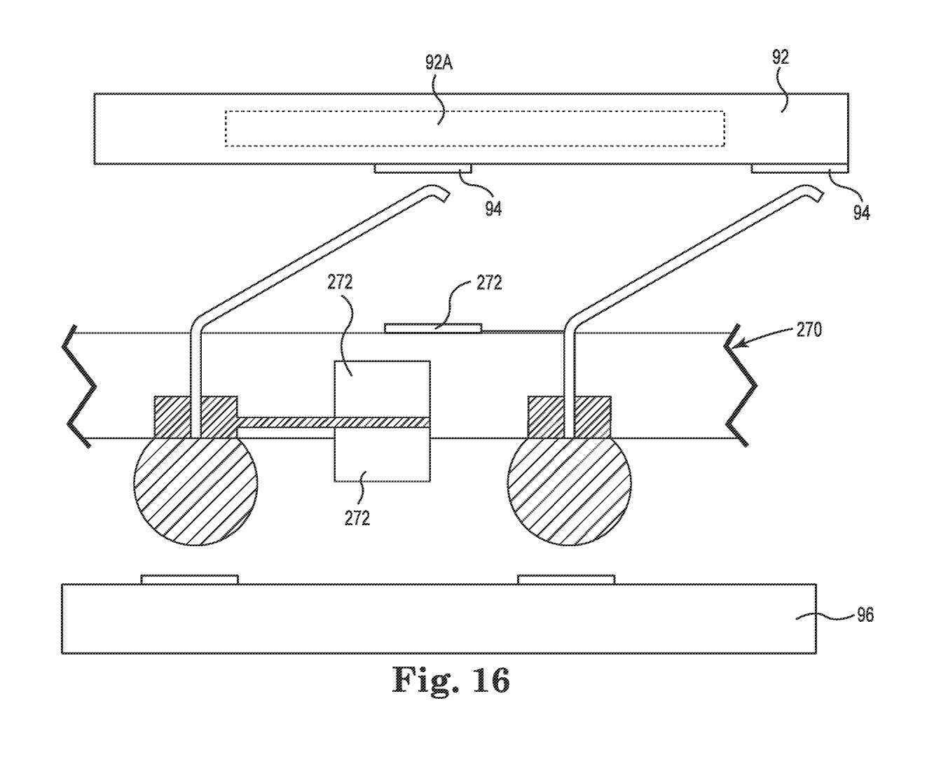

FIGS. 15 and 16 are cross-sectional views of interconnect assembly 270 containing additional electrical devices 272 in accordance with other embodiments of the present disclosure. The electrical devices 272 can be a power plane, ground plane, capacitor, resistor, filters, signal or power altering and enhancing device, memory device, embedded IC, RF antennae, and the like. The electrical devices 272 can be located on either surface 56, 58 of the substrate 52, or embedded therein. The electrical devices 272 can include passive or active functional elements. Passive structure refers to a structure having a desired electrical, magnetic, or other property, including but not limited to a conductor, resistor, capacitor, inductor, insulator, dielectric, suppressor, filter, varistor, ferromagnet, and the like.

FIGS. 15 and 16 illustrate the electrical devices 272 as internal decoupling capacitors located on the substrate 52 or within the interconnect assembly 270 between contact members 274. The electrical devices 272 can be added as discrete components or printed materials, reducing the need for discrete components on the first and second circuit members 92, 96. Moving the decoupling capacitors 272 closer to the first circuit member 92 also increases performance of the first circuit member 92.

The availability of printable silicon inks provides the ability to print the electrical devices 272, such as disclosed in the patents previously referenced and incorporated herein by reference. For example, the electrical devices 272 can be formed using printing technology, adding intelligence to the interconnect assembly 270. In particular, features that are typically located on the first or second circuit members 92, 96 can be incorporated into the interconnect assembly 270 in accordance with an embodiment of the present disclosure. According to one embodiment, the first circuit member 92 may comprise a package 92 having an integrated circuit 92A. The second circuit member 96 may be a PCB 96.

Locating such electrical devices on the interconnect assembly improves performance and enables a reduction in the cost of the integrated circuit 92A, the package 92, and the PCB 96. Integrated circuit manufactures are limited by the pitch that the PCB 96 can accommodate and still keep the printed circuit board to four layers. The integrated circuit makers can manufacture the package 92 with a smaller pitch, but with the pin counts is so high that the PCB 96 likely requires additional layers in order to route all of the signals.

The present interconnect assembly permits integrated circuit manufactures to reduce the pitch of the contacts 94 on the package 92, and perform any required signal routing in the interconnect assembly, rather than in the PCB 96 or by adding daughter boards to the system.

Integrated circuit manufactures also are limited by current socket designs when designing the configuration of contacts 94 on the package 92. Performing the routing in the present interconnect assembly permits quick and inexpensive changes. Similarly, locating the electrical devices 272 in the interconnect assembly permits integrated circuit manufactures to reduce or eliminate the capacitors currently located on the package 92 and PCB 96. This shift can greatly reduce cost and simplify the package 92 and PCB 96, while improving performance.

One of the reasons the contact members on prior art socket are so long (typically about 3 millimeters) is to provide clearance for the capacitors on the package 92 and the PCB 96 when the integrated circuit is put into the socket. Locating transistors and memory in the present interconnect assembly will permit the contact members to be shorter, which will improve the performance of the contacts.

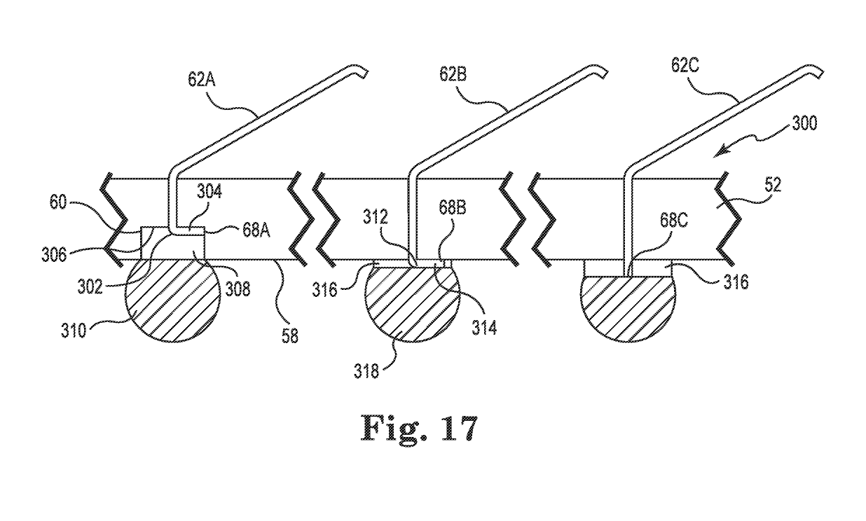

FIG. 17 is a cross-sectional view of an interconnect assembly 300 with various methods for securing contact members 62A-62C to the substrate 52 in accordance with other embodiments of the present disclosure. Proximal end 68A of contact member 62A is folded at location 302 to form retention tab 304. Retention tab 304 abuts bottom surface 306 of recess 60. Retention member 308 secures the retention tab 304 in the recess 60 and provides a surface for securing solder ball 310.

Proximal end 68B of contact member 62B is folded at location 312 to form retention tab 314. Retention tab 314 abuts second surface 58 of the substrate 52. No recess 60 is required. The retention tab 314 is secured to the substrate 52 by a retention member 316, such as for example a metal layer of sintered particles or metal plating. The retention member 316 also controls solder wetting during deposition of solder ball 318. Similarly, proximal end 68C of contact member 62C is also retained to the substrate 52 by a retention member 316.

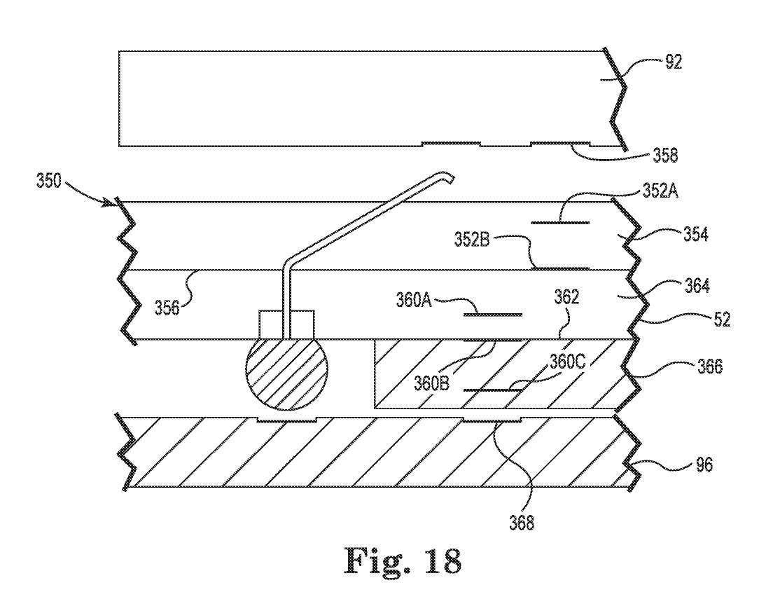

FIG. 18 is a cross-sectional view of an interconnect assembly 350 with various capacitive coupling features in accordance with another embodiment of the present disclosure. A capacitive coupling feature 352A is embedded in layer 354 of the substrate 52. A capacitive coupling feature 352B is located on second surface 356 of the layer 354. The capacitive coupling features 352A, 352B are positioned to electrically couple with contact pad 358 on first circuit member 92.

Capacitive coupling feature 360A is embedded in a layer 364 of the substrate 52. Capacitive coupling feature 360B is located on first surface 362 of the layer 364. The capacitive coupling features 360C is embedded in layer 366. All three capacitive coupling features 360A, 360B, 360C are positioned to electrically couple with contact pad 368 on the second member 96. The various capacitive coupling features in the embodiment of FIG. 18 are optionally formed using inkjet printing technology, aerosol printing technology, or other printing technology.

Where a range of values is provided, it is understood that each intervening value, to the tenth of the unit of the lower limit unless the context clearly dictates otherwise, between the upper and lower limit of that range and any other stated or intervening value in that stated range is encompassed within the embodiments of the invention. The upper and lower limits of these smaller ranges which may independently be included in the smaller ranges is also encompassed within the embodiments of the invention, subject to any specifically excluded limit in the stated range. Where the stated range includes one or both of the limits, ranges excluding either both of those included limits are also included in the embodiments of the invention.

Unless defined otherwise, all technical and scientific terms used herein have the same meaning as commonly understood by one of ordinary skill in the art to which the embodiments of the present disclosure belong. Although any methods and materials similar or equivalent to those described herein can also be used in the practice or testing of the embodiments of the present disclosure, the preferred methods and materials are now described. All patents and publications mentioned herein, including those cited in the Background of the application, are hereby incorporated by reference to disclose and described the methods and/or materials in connection with which the publications are cited.

The publications discussed herein are provided solely for their disclosure prior to the filing date of the present application. Nothing herein is to be construed as an admission that the present disclosure is not entitled to antedate such publication by virtue of prior invention. Further, the dates of publication provided may be different from the actual publication dates which may need to be independently confirmed.

Other embodiments of the invention are possible. Although the description above contains much specificity, these should not be construed as limiting the scope of the invention, but as merely providing illustrations of some of the presently preferred embodiments of this invention. It is also contemplated that various combinations or sub-combinations of the specific features and aspects of the embodiments may be made and still fall within the scope of the present disclosure. It should be understood that various features and aspects of the disclosed embodiments can be combined with or substituted for one another in order to form varying modes of the disclosed embodiments of the invention. Thus, it is intended that the scope of the present disclosure herein disclosed should not be limited by the particular disclosed embodiments described above.

Thus the scope of this invention should be determined by the appended claims and their legal equivalents. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment(s) that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims.

1-42. (canceled)

43. An interconnect assembly comprising:
a substrate comprising a plurality of through holes extending from a first surface to a second surface;
a plurality of recesses in the second surface of the substrate that at least partially overlap with the plurality of through holes, the recesses comprise a cross-sectional area greater than a cross-sectional area of the through holes;
a plurality of discrete contact members located in the plurality of the through holes, the plurality of contact members each comprising a proximal end accessible from the second surface, a distal end extending above the first surface, and an intermediate portion engaged with an engagement region of the substrate located between the first surface and the second surface; and
retention members at least partially located in the recesses and bonded to proximal ends of the contact members to retain the contact members in the through holes.

44. The interconnect assembly of claim 43, wherein the retention members comprise one or more of solder, solder paste, a conductive plug, a conductive adhesive, sintered conductive particles, electrical plating, or a combination thereof.

45. The interconnect assembly of claim 43, wherein the substrate comprises a plurality of layers.

46. The interconnect assembly of claim 43, wherein the substrate comprises at least one additional circuitry plane comprising one of a ground plane, a power plane, an electrical connection to other circuit members, a dielectric layer, a printed circuit board, a flexible circuit, a bare die device, an integrated circuit device, organic or inorganic substrates, or a rigid circuit.

47. The interconnect assembly of claim 43, wherein the intermediate portion of each of the plurality of contact members forms a friction fit with the engagement region of the substrate.

48. The interconnect assembly of claim 43, further comprising a solder ball attached to the retention member and electrically coupled to the proximal ends of each of the plurality of contact members.

49. The interconnect assembly of claim 43, wherein the proximal end of each of the plurality of contact members extends above the second surface and couples with a solder ball.

50. The interconnect assembly of claim 43, comprising a compliant material or a dielectric material between the retention members and at least a portion of an inner surface of the recesses.

51. The interconnect assembly of claim 43, further comprising a layer of dielectric material bonded to the first surface of the substrate.

52. The interconnect assembly of claim 51, wherein the layer of dielectric material limits deflection of the distal ends of the plurality of contact members.

53. The interconnect assembly of claim 43, further comprising:
a plurality of conductive traces located on at least one of the first and second surfaces of the substrate and electrically coupled to the plurality of contact members; and
a dielectric layer electrically insulating the conductive traces.

54. The interconnect assembly of claim 53, wherein the plurality of conductive traces comprise distal ends with a pitch different than a pitch of the proximal ends of the plurality of contact members.

55. The interconnect assembly of claim 53, further comprising a compliant layer located between one of the second surface and the plurality of conductive traces or between overlapping conductive traces.

56. The interconnect assembly of claim 53, further comprising a flexible circuit member electrically coupled to the plurality of conductive traces and extending beyond a perimeter edge of the substrate.

57. The interconnect assembly of claim 53, wherein the plurality of conductive traces electrically couple the interconnect assembly with a second interconnect assembly.

58. The interconnect assembly of claim 43 comprising a plurality of electrical devices printed on at least one of the first or second surfaces of the substrate and electrically coupled to at least one of the plurality of contact members.

59. An electrical assembly comprising:
the interconnect assembly of claim 43;
a first circuit member comprising contact pads compressively engaged with the distal ends of the plurality of contact members; and
a second circuit member comprising contact pads bonded to one or more of the retention members or one or more of the proximal ends of the plurality of contact members.

60. An electrical interconnect assembly for electrically interconnecting terminals on a first circuit member with terminals on a second circuit member, the electrical interconnect assembly comprising:
a substrate having a plurality of through holes extending from a first surface to a second surface and a plurality of recesses in the second surface of the substrate that at least partially overlap with the plurality of through holes, each recess having a cross-sectional area greater than a cross-sectional area of a corresponding overlapping through hole;
a plurality of contact members located in the plurality of through holes, each of the plurality of contact members comprising a proximal end extending at least partially into one of the plurality of recesses in the second surface, a distal end extending above the first surface and adapted to electrically couple with a terminal on the first circuit member, and an intermediate portion engaged with an engagement region of the substrate located between the first surface and the one of the plurality of recesses; and
a plurality of electrically conductive retention members at least partially located in the recesses and bonded the proximal ends of the contact members.

61. A method of forming an interconnect assembly comprising:
forming a substrate with a plurality of through holes extending from a first surface to a second surface;
forming a plurality of recesses in the second surface of the substrate that at least partially overlap with the plurality of through holes, the recesses comprise a cross-sectional area greater than a cross-sectional area of the through holes;
inserting a plurality of discrete contact members in the plurality of through holes, the contact members comprising proximal ends accessible from the second surface, distal ends extending above the first surface, and intermediate portions engaged with an engagement region of the substrate located between the first surface and the recesses;
depositing retention members at least partially in the recesses; and
bonding the retention members to the proximal ends to retain the contact members in the through holes.

62. The method of claim 61 comprising printing the retention members in the recesses.

63. The method of claim 61, further comprising forming the substrate from a plurality of layers.

64. The method of claim 61, further comprising forming at least one additional circuitry plane on the substrate.

65. The method of claim 61, further comprising frictionally engaging the intermediate portion of the contact member with the engagement region of the substrate.

66. The method of claim 61, further comprising attaching solder balls to the plurality of retention members and electrically coupling the solder balls with the proximal ends of the plurality of contact members.

67. The method of claim 61, further comprising depositing one of a compliant material or a dielectric material between the retention members and at least a portion of inner surfaces of the recesses.

68. The method of claim 61, further comprising:
forming a plurality of conductive traces on at least one of the first and second surfaces of the substrate; and
electrically coupling the conductive traces with the plurality of contact members.

69. The method of claim 68, comprising configuring the plurality of conductive traces with a pitch different than a pitch of the proximal ends of the contact members.

70. The method of claim 68, further comprising depositing a compliant layer between one of the second surface and the conductive traces or between overlapping conductive traces.

71. The method of claim 68, further comprising electrically coupling a flexible circuit member to the conductive traces and extending the flexible circuit member beyond a perimeter edge of the substrate.

72. The method of claim 68, further comprising electrically coupling the plurality of conductive traces with a second interconnect assembly.

73. The method of claim 61, further comprising:
printing a plurality of electrical devices on the substrate; and
electrically coupling each of the plurality of electrical devices to at least one of the plurality of contact members.

74. The method of claim 61, further comprising:
compressively engaging contact pads on a first circuit member with distal ends of the contact members; and
bonding contact pads on a second circuit member to the proximal end of one or more of the contact members or to one or more of the retention members.
